(19) United States
(12) Patent Application Publication
(10) Pub. No.: US 2009/0126786 A1
(43) Pub. Date: May 21, 2009

(54) Selective Emitter and Texture Processes for Back Contact Solar Cells

(75) Inventors: Jason Dominguez, Albuquerque, NM (US); Peter Hacke, Albuquerque, NM (US); Damion Cummings, Albuquerque, NM (US)

Correspondence Address: PEACOCK MYERS, P.C., 201 THIRD STREET, N.W., SUITE 1340, ALBUQUERQUE, NM, 87102, US

(73) Assignee: ADVENT SOLAR, INC., Albuquerque, NM (US)

(21) Appl. No.: 12/270,456

(22) Filed: Nov. 13, 2008

Related U.S. Application Data
(60) Provisional application No. 60/987,554, filed on Nov. 13, 2007.

(51) Int. Cl. H01L 31/00; B01J 19/08

(52) U.S. Cl. 136/256; 427/569

(57) ABSTRACT

Methods for manufacturing textured selective emitter back contact solar cells, and solar cells made in accordance therewith. A separate antireflective coating is preferably deposited, which also preferably provides simultaneous hydrogen passivation. The high sheet resistance and low sheet resistance selective emitter diffusions may be performed in either order.

### CROSS-REFERENCE TO RELATED APPLICATIONS

This application claims the benefit of the filing of U.S. Provisional Patent Application Ser. No. 60/987,554, entitled “Selective Emitter and Texture Processes for Back Contact Solar Cells”, filed on Nov. 13, 2007, the specification of which is incorporated herein by reference.

### BACKGROUND OF THE INVENTION

1. Field of the Invention (Technical Field)

The present invention comprises methods for manufacturing selective emitter and textured solar cells, and solar cells made according to those methods.

2. Description of Related Art

Note that the following discussion refers to a number of publications by author(s) and year of publication, and that due to recent publication dates certain publications are not to be considered as prior art vis-à-vis the present invention. Discussion of such publications herein is given for more complete background and is not to be construed as an admission that such publications are prior art for patentability determination purposes.

Back contact solar cells, for example emitter wrap through (EWT) solar cells, comprising a selective emitter structure have high sheet resistance (and optionally deep) front-side emitter diffusions combined with low sheet resistance (i.e. more heavily doped) emitter diffusions on the cell rear and in the EWT holes. The front sheet resistance is made high so that reduced minority carrier recombination, reduced surface recombination velocity, and UV/blue spectral response nearing unity can be achieved. The other emitter regions have low sheet resistance so that series resistance can be lowered and surface field effects can be achieved under the metal rear contacts to improve cell voltage. In general, this results in improved front surface passivation, improved current collection and higher open circuit voltage (V_{oc}). In the case of a p-type base cell, the emitters are n+.

It is also advantageous for solar cells to be textured on the front surface to improve light trapping. However, an untextured rear surface allows for better patterning of device structures on the rear side and better surface passivation.

One process for manufacturing a textured selective emitter EWT cell is disclosed in Neu et al., “Low-cost multicrystalline back-contact silicon solar cells with screen printed metallization”, PVSEC (International Photovoltaic Science and Engineering Conference) 12, 2001, published in Solar Energy Materials and Solar Cells, Volume 74, Number 1, October 2002, pp. 139-146(8). However, this process results in a poorly passivated front surface and non-optimized anti-reflection (AR) coating.

### BRIEF SUMMARY OF THE INVENTION

The present invention is a method for manufacturing a back contact solar cell, the method comprising the steps of texturing the front surface of the solar cell, performing a first emitter diffusion; depositing a barrier layer on the front surface; removing at least a portion of the first emitter diffusion from the rear surface of the solar cell; performing a second emitter diffusion in a desired pattern on the rear surface; removing the barrier layer from the front surface; and depositing an antireflective coating on the front surface. The first emitter diffusion preferably provides a higher sheet resistance than the second emitter diffusion. One or both depositing steps are preferably performed using Plasma Enhanced Chemical Vapor Deposition (PECVD). The barrier layer and/or the antireflective coating preferably comprise SiN. One or both depositing steps preferably further comprise providing simultaneous hydrogen passivation. The barrier layer optionally comprises a different material than the antireflective coating.

The present invention is also a back contact solar cell comprising a textured front surface; a front side emitter comprising a first sheet resistance; a back side emitter comprising a second sheet resistance lower than said first sheet resistance; and an antireflective coating comprising an index of refraction of greater than approximately 2.01. The antireflective coating preferably comprises PECVD-deposited SiN. The solar cell preferably comprises a surface recombination velocity of less than 1000 cm/s, more preferably less than 15 cm/s, and most preferably less than 1 cm/s. The front side emitter optionally comprises a depth of less than approximately 0.35 microns.

The present invention is also a method for manufacturing a back contact solar cell, the method comprising the steps of performing a first emitter diffusion on the rear side of the solar cell, and subsequently performing a second emitter diffusion on the rear side and the front side of the solar cell, the second emitter diffusion providing a higher sheet resistance than the first emitter diffusion. The method preferably further comprises the steps of texturing the front surface of the solar cell and depositing a barrier layer on the front surface prior to performing the first emitter diffusion, removing the barrier layer after performing the first emitter diffusion and before performing the second emitter diffusion, and depositing an antireflective coating on the front surface after performing the second emitter diffusion. One or both depositing steps are preferably performed using Plasma Enhanced Chemical Vapor Deposition (PECVD). The barrier layer and/or the antireflective coating preferably comprise SiN. One or both depositing steps preferably further comprise providing simultaneous hydrogen passivation. The barrier layer optionally comprises a different material than the antireflective coating.

Objects, advantages and novel features, and further scope of applicability of the present invention will be set forth in part in the detailed description to follow, taken in conjunction with the accompanying drawings, and in part will become apparent to those skilled in the art upon examination of the following, or may be learned by practice of the invention. The objects and advantages of the invention may be realized and attained by means of the instrumentalities and combinations particularly pointed out in the appended claims.

### DETAILED DESCRIPTION OF THE INVENTION

The present invention comprises processes to produce one-side textured, one-side untextured back contact (including but not limited to EWT) cells while simultaneously providing a selective emitter, and solar cells made therefrom.

One embodiment of the present invention is a process to texture the front surface of a back contact solar cell which does not comprise a selective emitter. The steps are as follows:

1. Texture wafer, for example using plasma etching, wet texturing, KOH, or a single or double side acidic texture etch (ATE), optionally isotextured

2. Apply front side barrier (e.g. comprising SiN) to protect textured front surface

3. Laser drill vias

4. Etch to remove laser damage from vias, smooth texture from rear surface, and remove front side barrier. One such etch process comprises etching successively with KOH, HCl, and HF with water rinses after each step.

5. Print/fire rear side diffusion barrier (DB)

6. Emitter POCl₃ diffusion

7. Deglaze (remove P₂O₅ glass) and remove front side barrier, preferably using 10:1 HF solution

8. Apply front surface anti-reflective (AR) coating (comprising for example SiN), preferably using PECVD

9. Print/fire p-metal and n-metal

10. Testing

One embodiment of a method to create a selective emitter in the cell may be accomplished by a modification of the aforesaid process as follows:

1. Texture wafer, for example using plasma etching, wet texturing, KOH, or a single or double side acidic texture etch (ATE), optionally isotextured

2. High Rₛₕₑₑₜ POCl₃ diffusion over entire wafer, producing an emitter structure having a sheet resistance preferably between approximately 60-1201/sq, more preferably between approximately 60-1001/sq, and most preferably approximately 701/sq.

3. Deglaze, preferably with HF

4. Apply front side barrier (e.g. comprising SiN) to protect textured front surface

5. Laser drill vias

6. Etch to remove laser damage from vias and remove texture and emitter from rear surface, preferably using KOH

7. Print/fire rear side diffusion barrier (DB)

8. Low Rₛₕₑₑₜ emitter POCl₃ diffusion on rear side (where there is no DB) and in vias, producing an emitter having a sheet resistance preferably between approximately 5-50 Ω/sq, more preferably between approximately 20-40 Ω/sq, and most preferably approximately 35 Ω/sq.

9. Deglaze and remove front side barrier, preferably using 10:1 HF solution

10. Apply front surface anti-reflective (AR) coating (comprising for example SiN)

11. Print/fire p-metal and n-metal

12. Testing

Steps 4 and 10 are preferably performed via Plasma Enhanced Chemical Vapour Deposition (PECVD). Low Pressure Chemical Vapour Deposition (LPCVD), as used in previous selective emitter processes, results in a denser, more stable stoichiometric barrier layer. Although this enables the elimination of the step of depositing an AR coating, the properties of the resulting layer cannot be tuned because it is so stable and must withstand all of the subsequent processing steps. In addition, LPCVD cannot simultaneously passivate the cell with hydrogen, so the use of this process requires a separate hydrogen passivation step.

In contrast, while PECVD does not result in as robust a layer, it is easier to remove (for example via a standard HF etch), so it can be sacrificial. By depositing a new AR coating after most of the processing steps, its optical, physical, and/or other properties can be optimized. For example, a PECVD deposited layer can have a wide composition range, as well as a variable Si or H content. In addition, the index of refraction for a PECVD-deposited layer typically ranges from about 2.25-2.3, which is a better match to glass than the index of refraction of an LPCVD-deposited layer (typically about 1.95-2.01), providing better module performance. Finally, not only does deposition of, for example, SiN using the PECVD process simultaneously hydrogen passivate the cell, the passivation achieved is far better than that provided by a separate hydrogen passivation step. For example, LPCVD SiN combined with separate plasma hydrogen passivation processes typically result in surface recombination velocities (SRV) of over 1000 cm/s, while passivation during barrier deposition can result in SRV as low as 0.25 cm/s.

Step 4 may comprise depositing any diffusion barrier material using any known process, for example Atmospheric Pressure Chemical Vapour Deposition (APCVD) SiO₂, atomic layer deposition Al₂O₃, thermal SiO₂, PECVD SiC, SiN stack, or thermal SiO₂/PECVD SiN. Unlike with existing selective emitter cells, this material may be different than the AR coating. It is preferable, though not required, that the material is easily removed.

The high temperature required for step 8 can densify the front side barrier, making it harder to remove, so the amount of the front side barrier material deposited is preferably sufficient to protect the front side surface etch, but little enough to be removed in step 9.

An alternative embodiment of a process for manufacturing a textured selective emitter back contact solar cell is as follows:

1. Texture wafer, for example using plasma etching, wet texturing, KOH, or a single or double side acidic texture etch (ATE), optionally isotextured

2. Apply front side barrier (e.g. comprising SiN) to protect textured front surface

3. Laser drill vias

4. Etch to remove laser damage from vias and remove texture from rear surface

5. Print/fire rear side diffusion barrier (DB) (comprising for example a transition metal oxide, such as TiO₂ or Ta₂O₅, optionally doped with phosphorous)

6. Low Rₛₕₑₑₜ POCl₃ diffusion on rear side (where there is no DB) and in vias

7. Deglaze (remove phosphorous glass) and etch off front side barrier

8. High Rₛₕₑₑₜ Emitter POCl₃ diffusion

9. Deglaze preferably using HF

10. Apply front surface anti-reflective (AR) coating (comprising for example SiN)

11. Print/fire p-metal and n-metal

12. Testing

In this process, the heavy rear side emitter diffusion (step 6) is performed before the lighter, lower temperature diffusion (step 8), which also diffuses more phosphorus into the rear side and vias in addition to the existing low resistance diffusion, thereby lowering the resistance even further. This process typically results in a shallower front side junction, typically between approximately 0.1-0.35 microns deep, as opposed to approximately 0.35 to 0.8 microns for other processes.

Although the invention has been described in detail with particular reference to these preferred embodiments, other embodiments can achieve the same results. Variations and modifications of the present invention will be obvious to those skilled in the art and it is intended to cover all such modifications and equivalents. The entire disclosures of all references, applications, patents, and publications cited above and/or in the attachments, and of the corresponding application(s), are hereby incorporated by reference.

What is claimed is:

1. A method for manufacturing a back contact solar cell, the method comprising the steps of:
texturing a front surface of the solar cell;
performing a first emitter diffusion;
depositing a barrier layer on the front surface;
removing at least a portion of the first emitter diffusion from a rear surface of the solar cell;
performing a second emitter diffusion in a desired pattern on the rear surface;
removing the barrier layer from the front surface; and
depositing an antireflective coating on the front surface.

2. The method of claim 1 wherein the first emitter diffusion provides a higher sheet resistance than the second emitter diffusion.

3. The method of claim 1 wherein one or both depositing steps are performed using Plasma Enhanced Chemical Vapor Deposition (PECVD).

4. The method of claim 3 wherein the barrier layer and/or the antireflective coating comprise SiN.

5. The method of claim 1 wherein one or both depositing steps further comprise providing simultaneous hydrogen passivation.

6. The method of claim 1 wherein the barrier layer comprises a different material than the antireflective coating.

7. A back contact solar cell comprising:
a textured front surface;
a front side emitter comprising a first sheet resistance;
a back side emitter comprising a second sheet resistance lower than said first sheet resistance; and
an antireflective coating comprising an index of refraction of greater than approximately 2.01.

8. The back contact solar cell of claim 7 wherein said antireflective coating comprises PECVD-deposited SiN.

9. The back contact solar cell of claim 7 comprising a surface recombination velocity of less than 1000 cm/s.

10. The back contact solar cell of claim 9 comprising a surface recombination velocity of less than 15 cm/s.

11. The back contact solar cell of claim 10 comprising a surface recombination velocity of less than 1 cm/s.

12. The back contact solar cell of claim 7 wherein said front side emitter comprises a depth of less than approximately 0.35 microns.

13. A method for manufacturing a back contact solar cell, the method comprising the steps of:
performing a first emitter diffusion on a rear side of the solar cell;
subsequently performing a second emitter diffusion on the rear side and a front side of the solar cell, the second emitter diffusion providing a higher sheet resistance than the first emitter diffusion.

14. The method of claim 13 further comprising the steps of:
texturing a front surface of the solar cell and depositing a barrier layer on the front surface prior to performing the first emitter diffusion;
removing the barrier layer after performing the first emitter diffusion and before performing the second emitter diffusion; and
depositing an antireflective coating on the front surface after performing the second emitter diffusion.

15. The method of claim 14 wherein one or both depositing steps are performed using Plasma Enhanced Chemical Vapor Deposition (PECVD).

16. The method of claim 15 wherein the barrier layer and/or the antireflective coating comprise SiN.

17. The method of claim 14 wherein one or both depositing steps further comprise providing simultaneous hydrogen passivation.

18. The method of claim 14 wherein the barrier layer comprises a different material than the antireflective coating.
